(19) United States
(12) Patent Application Publication
(10) Pub. No.: US 2023/0397395 A1
(43) Pub. Date: Dec. 7, 2023

(54) MEMORY DEVICE INCLUDING SEMICONDUCTOR ELEMENT

(71) Applicant: Unisantis Electronics Singapore Pte. Ltd., Singapore (SG)

(72) Inventors: Nozomu HARADA, Tokyo (JP); Koji SAKUI, Tokyo (JP)

(21) Appl. No.: 18/235,673

(22) Filed: Aug. 18, 2023

Related U.S. Application Data
(63) Continuation-in-part of application No. PCT/JP2021/007060, filed on Feb. 25, 2021.

(51) Int. Cl. H10B 12/00; G11C 11/4096; H01L 29/10; H01L 29/423; H01L 29/78

(52) U.S. Cl. CPC H10B 12/20; G11C 11/4096; H01L 29/1095; H01L 29/4238; H01L 29/42376; H01L 29/7841

(57) ABSTRACT

A first Si pillar and a second Si pillar are disposed above a substrate. The first Si pillar stands in a perpendicular direction. In plan view, the outer periphery line of the second Si pillar is located inside the outer periphery line of the first Si pillar. An N⁺ layer connected to a source line and an N⁺ layer connected to a bit line are disposed at both ends of the first and second Si pillars. A first gate insulating layer surrounds the first Si pillar. A first gate conductor layer surrounds the first gate insulating layer and is connected to a plate line. A second gate conductor layer surrounds a gate HfO₂ layer surrounding the second Si pillar and is connected to a word line. Voltages applied to the source line, the plate line, the word line, and the bit line are controlled to perform a data hold operation of holding a group of holes generated by an impact ionization phenomenon or a gateinduced drain leakage current in a channel region of the Si pillar and a data erase operation of discharging the group of holes from the channel region.

### CROSS REFERENCES TO RELATED APPLICATIONS

The present application is a Continuation-In-Part application of PCT/JP2021/007060, filed Feb. 25, 2021, the entire contents of which are incorporated herein by reference.

### BACKGROUND OF THE INVENTION

### 1. Field of the Invention

The present invention relates to memory devices including semiconductor elements.

### 2. Description of the Related Art

Recently, there has been a need for a higher degree of integration and a higher performance of memory elements in large-scale integration (LSI) technology development.

A channel of a typical planar metal-oxidesemiconductor (MOS) transistor extends in a direction parallel to an upper surface of a semiconductor substrate. In contrast, a channel of a surrounding-gate transistor (SGT) extends in a direction perpendicular to an upper surface of a semdconductor substrate (see, for example, Japanese Unexamined Patent Application Publication No. 2-188966 and Hiroshi Takata, Kazumasa Sunbuchi, Naoko Okabe, Akindro Nitayama, Katsuhiko Hieda, Fumio Horiguchi, and Fujio Masuoka: IEEE Transaction on Electron Devices, Vol. 38, No. 3, pp. 573-578 (1991)). Thus, SGTs allow for higher densities of semiconductor devices than planar MOS transistors. SGTs can be used as select transistors to achieve higher degrees of integration of devices such as dynamic random-access memory (DRAM; see, for example, H. Chung, H. Kim, H. Kim, K. Kim, S. Kim, K. W. Song, J. Kim, Y. C. Oh, Y. Hwang, H. Hong, G. Jdn, and C. Chung: “4F2 DRAM Cell with Vertical Pillar Transistor (VPT),” 2011 Proceeding of the European Solid-State Device Research Conference (2011)), which has a capacitor connected thereto; phasechange memory (PCM; see, for example, H. S. Philip Wong, S. Raoux, S. Kim, Jiale Liang, J. R. Reifenberg, B. Rajendran, M. Asheghi, and K. E. Goodson: “Phase Change Memory,” Proceeding of IEEE, Vol. 98, No. 12, December, pp. 2201-2227 (2010)) and resistive random-access memory (BRAN; see, for example, K. Tsunoda, H. Kinoshita, H. Noshiro, Y. Yamazaki, T. Iizuka, Y. Ito, A. Takahashi, A. Okano, Y. Sato, T. Fukano, M. Aoki, and Y. Sugiyama: “Low Power and High Speed Switching of Ti-doped NiO ReRAM under the Unipolar Voltage Source of less than 3 V,” IEDM (2007)) , which have a variable-resistance element connected thereto; and magnetoresistive random-access memory (MRAM; see, for example, W. Kang, L. Zhang, J. Klein, Y. Zhang, D. Ravelosona, and W. Zhao: “Reconfigurable Codesign of STT-MRAM Under Process Variations in Deeply Scaled Technology,” IEEE Transaction on Electron Devices, pp. 1-9 (2015)), in which the resistance changes as the magnetic spin orientation changes with current. There are also, for example, DRAM memory cells composed of a single MOS transistor without a capacitor (see M. G. Ertosun, K. Lim, C. Park, J. Oh, P. Kirsch, and K. C. Saraswat: “Novel Capacitoriess Single-Transistor Charge-Trap DRAM (1T CT DRAM) Utilizing Electron,” IEEE Electron Device Letter, Vol. 31, No. 5, pp. 405-407 (2010)). The present application relates to a dynamic flash memory that can be composed only of a MOS transistor without a variable-resistance element or a capacitor.

FIGS. 8A, 8B, 8C and 8D illustrate the write operation of a DRAM memory cell composed of a single MOS transistor without a capacitor as mentioned above, FIGS. 9A and 9B illustrate a problem with its operation, and FIGS. 10A, 10B and 10C illustrate its read operation (see M. G. Ertosun, K. Lim, C. Park, J. Oh, P. Kirsch, and K. C. Saraswat: “Novel Capacitoriess Single-Transistor Charge-Trap DRAM (1T CT DRAM) Utilizing Electron,” IEEE Electron Device Letter, Vol. 31, No. 5, pp. 405-407 (2010); J. Wan, L. Roler, A. Zaslaysky, and S. Critoloveanu: “A Compact Capacitor-Less High-Speed DRAM Using Field Effect-Controlled Charge Regeneration,” Electron Device Letters, Vol. 35, No. 2, pp. 179-181 (2012); T. Ohsawa, K. Fuldta, T. Higashi, Y. lwata, T. Kajiyama, Y. Asao, and X. Sunouchi: “Memory design using a one-transistor gain cell on SOI” IEEE JSSC, Vol. 37, No. 11, pp. 1510-1522 (2002); T. Shino, N. Kusunoki, T. Higashi, T. Ohsawa, K. Fujita, K. Hatsuda, N. Ikumi, F. Matsuoka, Y. Kajitarii, F. Fukuda, Y. Watanabe, Y. Minami, A. Sakamoto, J. Nishimura, H. Nakalima, M. Morikado, K. Inch, T. Hamamoto, and A. Nitayama: “Floating Body PAM Technology and its Scalability to 32 nm Node and Beyond,” IEEE IEDM (2006); and E. Yoshida and T. Tanaka: “A Design of a Capacitorless 1T-DRAM Cell Using Gate-Induced Drain-Leakage (GIDL) Current for Low-Power and High-Speed Embedded Memory,” IEEE IEDM (2003)).

FIGS. 8A, 8B, 8C and 8D illustrate the write operation of the DRAM memory cell. FIG. 8A illustrates a “1” written state. Here, the memory cell is formed on a sjIjcon-on-insulator (SOI) substrate 100 and is composed of a source N⁺ layer 103 (a semiconductor region containing a high concentration of a donor impurity is hereinafter referred to as “N⁺ layer”) having a source line SL connected thereto, a drain N⁺ layer 104 having a bit, line BL connected thereto, a gate conductive layer 105 having a word line WL connected thereto, and a floating body 102 of a MOS transistor 110a; that is, the DRAM memory cell is composed of the single MOS transistor 110a without a capacitor. A SiO₂ layer 101 of the SOI substrate 100 is disposed directly under and in contact with the floating body 102. When “1” is written in the memory cell composed of the single MOS transistor 110a, the MOS transistor 110a is operated in the saturation region. Specifically, an electron channel 107 extending from the source N⁺ layer 103 has a pinch-off point 108 and does not reach the drain N⁺ layer 104 having the bit line BL connected thereto. When the MOS transistor 110a is operated such that both the bit line BL connected to the drain N⁺ layer 104 and the word line WL connected to the gate conductive layer 105 are set to a high voltage and the gate voltage is about half the drain voltage, the maximum electric field intensity is reached at the pinch-off point 108 near the drain N⁺ layer 104. As a result, accelerated electrons flowing from the source N⁺ layer 103 toward the drain N⁺ layer 104 collide with the Si lattice, and the kinetic energy lost in the collision generates electron-hole pairs. Most of the generated electrons (not illustrated) reach the drain N⁺ layer 104. In addition, an extremely small proportion of very hot electrons traverse the gate oxide film 109 to reach the gate conductive layer 105. A group of holes 106 generated at the same time charge the floating body 102. In this case, the generated holes contribute as additional majority carriers in the floating body 102, which is P-type Si. When the floating body 102 is filled with the group of generated holes 106, and the voltage of the floating body 102 is higher than that of the source N⁺ layer 103 by Vb or more, additional generated holes are discharged to the source N⁺ layer 103. Here, Vb is the built-in voltage of the PN junction between the source N⁺ layer 103 and the P layer forming the floating body 102, and is about 0.7 V. FIG. 8B illustrates a situation in which the floating body 102 has been charged to saturation with the group of generated holes 106.

Next, the “0” write operation of the memory cell 110 will be described with reference to FIG. 8C. A memory cell 110a having “1” written therein and a memory cell 110b having “0” written therein are randomly present for a common selected word line WL. FIG. 8C illustrates a situation in which a “1” written state is rewritten to a “0” written state. In “0” writing, the voltage of the bit line BL is negatively based so that the PN junction between the drain N⁺ layer 104 and the P layer forming the floating body 102 is forward-biased. As a result, the group of holes 106 generated in the floating body 102 in advance in the previous cycle flow into the drain N⁺ layer 104 connected to the bit line BL. Upon completion of the write operation, two memory cell states, i.e., the memory cell 110a filled with the group of generated holes 106 (FIG. 8B) and the memory cell 110b having the group of generated holes 106 discharged therefrom (FIG. 8C), are obtained. The potential of the floating body 102 of the memory cell 110a filled with the group of holes 106 is higher than that of the floating body 102 having no generated holes therein. Thus, the threshold voltage of the memory cell 110a is lower than the threshold voltage of the memory cell 110b. This situation is illustrated in FIG. 8D.

Next, a problem with the operation of the memory cell composed of a single MOS transistor will be described with reference to FIGS. 9A and 9B. As illustrated in FIG. 9A, the capacitance C_{FB} of the floating body 102 is the sum of the capacitance C_{WL} between the gate having the word line connected thereto and the floating body 102, the junction capacitance C_{SL} of the SN junction between the source N⁺ layer 103 having the source line connected thereto and the floating body 102, and the junction capacitance C_{BL} of the PN junction between the drain N⁺ layer 104 having the bit line connected thereto and the floating body 102, as expressed by the following equation:

C_{FB}=C_{WL}+C_{BL}+C_{BL} (1)

Hence, when the word line voltage V_{WL} oscillates during writing, it also affects the voltage of the floating body 102, which serves as the storage node (contact) of the memory cell. This situation is illustrated in FIG. 9B. As the word line voltage V_{WL} increases from 0 V to V_{ProgWL} during writing, the voltage V_{FB} of the floating body 102 increases from a voltage V_{FB1} in the initial state before the change in word line voltage to V_{FB2} due to capacitive coupling with the word line. The change in voltage ΔV_{FB} is expressed by the following equation:

$$\begin{matrix}{ΔV}_{FE} = {V}_{FB 2} - {V}_{FB 1} \\ {C}_{WL} / ( {C}_{WL} + {C}_{BL} + {C}_{SL} ) \times {V}_{ProgWL}\end{matrix} \qquad ( 2 )$$

### Here,

β=C_{WL}/(C_{WL}+C_{BL}+C_{SL}) (3)

where β is referred to as coupling rate. In this memory cell, the contribution ratio of C_{WL} is large, for example, C_{WL}:C_{BL}:C_{SL}=8:1:1. In this case, β=0.8. For example, when the word line voltage changes from 5 V during writing to 0 V upon completion of writing, the floating body 102 is subjected to oscillation noise due to capacitive coupling between the word line and the floating body 102, i.e., 5 V×β=4 V. This causes a problem in that a sufficient margin of potential difference between the “1” potential and “0” potential of the floating body 102 cannot be achieved in writing.

FIGS. 10A, 10B and 10C illustrate the read operation. FIG. 10A illustrates a “1” written state, and FIG. 10B illustrates a “0” written state. In practice, however, even if Vb has been written in the floating body 102 by “1” writing, the floating body 102 is lowered to a negative bias when the word line returns to 0 V upon completion of writing. When “0” is written, the floating body 102 is further negatively biased. Thus, as illustrated in FIG. 10C, a sufficient margin of potential difference between “1” and “0” cannot be achieved in writing. This small margin of operation is a considerable problem with this DRAM memory cell. In addition, it is desirable to achieve a higher density of DRAM memory cells.

A capacitorless one-transistor DRAM (gain cell) configured as a memory device including an SGT has a problem in that, when the word line potential oscillates during data reading and writing, it is directly transmitted as noise to the body of the SGT because of large capacitive coupling between the word line and the floating body of the SGT. This causes the problem of erroneous reading and erroneous rewriting of stored data and thus makes it difficult to put the capacitorless one-transistor DRAM (gain cell) to practical use. In addition to solving the above problem, there is a need for a higher density of DRAM memory cells.

SUMMARY OF THE INVENTION

To solve the above problems, a memory device including a semiconductor element according to the present invention includes a first semiconductor base disposed above a substrate, the first semiconductor base standing in a direction perpendicular to the substrate or extending in a direction parallel to the substrate; a second semiconductor base connected to the first semiconductor base and extending in the same direction as the first semiconductor base; a first impurity region connected to the first semiconductor base; a second impurity region connected to the second semiconductor base; a first gate insulating layer surrounding a portion or an entirety of a side surface of the first semiconductor base; a second gate insulating layer surrounding a portion or an entirety of a side surface of the second semiconductor base; a first gate conductor layer covering the first gate insulating layer; and a second gate conductor layer covering the second gate insulating layer. In a sectional view as viewed in an extension direction in which the first semiconductor base and the second semiconductor base are connected together, an outer periphery line of the first semiconductor base at a junction between the first semiconductor base and the second semiconductor base is identical to or located outside an outer periphery line of the second semiconductor base at the junction, and an outer periphery line of the second semiconductor base at a position away from the junction is located inside the outer periphery line of the first semiconductor base. Voltages applied to the first impurity region, the second impurity region, the first gate conductor layer, and the second gate conductor layer are controlled to perform a data write operation, a data read operation, and a data erase operation (first aspect).

In the first aspect, the length of the first semiconductor base may be longer than or equal to the length of the second semiconductor base in the extension direction in which the first semiconductor base and the second semiconductor base are connected together (second aspect).

In the first aspect, the area of a surface of the first gate conductor layer may be greater than the area of a surface of the second gate conductor layer (third aspect).

In the first aspect, the extension direction in which the first semiconductor base and the second semiconductor base are connected together may be a direction perpendicular to the substrate, and in plan view, an outer periphery line of the second semiconductor base at a position adjoining the second impurity region may be located inside an outer periphery line of the second semiconductor base at a position adjoining the first semiconductor base (fourth aspect).

In the first aspect, the extension direction in which the first semiconductor base and the second semiconductor base are connected together may be a direction perpendicular to the substrate, and in plan view, an outer periphery line of the first semiconductor base at a position adjoining the first impurity region may be located outside an outer periphery line of the first semiconductor base at a position adjoining the second semiconductor base (fifth aspect).

In the first aspect, a wiring line connected to the first impurity region may be a source line, a wiring line connected to the second impurity region may be a bit line, a wiring line connected to the first gate conductor layer may be a first drive control line, a wiring line connected to the second gate conductor layer may be a word line, and voltages applied to the source line, the bit line, the first drive control line, and the word line may be controlled to perform the data erase operation, the data write operation, and the data read operation (sixth aspect).

In the first aspect, a first gate capacitance between the first gate conductor layer and the first semiconductor base may be greater than a second gate capacitance between the second gate conductor layer and the second semiconductor base (seventh aspect).

In the first aspect, the memory device including a semiconductor element may include the first semiconductor base standing perpendicular to the substrate; the second semiconductor base standing on the first semiconductor base; the first impurity region on the substrate; the second impurity region on the second semiconductor base; the first gate insulating layer surrounding a portion or the entirety of the side surface of the first semiconductor base; the second gate insulating layer surrounding a portion or the entirety of the side surface of the second semiconductor base; the first gate conductor layer surrounding the first gate insulating layer; the second gate conductor layer surrounding the second gate insulating layer; and a first insulating layer between the first gate conductor layer and the second gate conductor layer (eighth aspect)

In the first aspect, the cross-sectional area of the first semiconductor base at a position adjoining the second semiconductor base may be smaller than the cross-sectional area of the first semiconductor base at a position adjoining the first impurity region (ninth aspect).

In the first aspect, the cross-sectional area of the second semiconductor base at a position adjoining the first semiconductor base may be greater than the cross-sectional area of the second semiconductor base at a position adjoining the second impurity region (tenth aspect).

In the first aspect, the first impurity region, the second impurity region, the first gate conductor layer, and the second gate conductor layer may be configured to perform a data write operation of generating a group of electrons and a group of holes by an impact ionization phenomenon with a current flowing between the first impurity region and the second impurity region or by a gate-induced drain leakage current in a first boundary region between the first semiconductor base and the second semiconductor base, in a second boundary region between the first impurity region and the first semiconductor base, or in a third boundary region between the second impurity region and the second semiconductor base, discharging, of the group of generated electrons and the group of generated holes, the group of electrons from the first semiconductor base and the second semiconductor base, and allowing some or all of the group of holes to remain in one or both of the first semiconductor base and the second semiconductor base; and a data erase operation of discharging, of the group of holes, a group of remaining holes from the first semiconductor base and the second semiconductor base (eleventh aspect).

In the first aspect, one or both of the first gate conductor layer and the second gate conductor layer may be split into two segments in a cross-section in a direction perpendicular Co the direction in which the first semiconductor base and the second semiconductor base extend (twelfth aspect).

In the first aspect, the first gate conductor layer may be split into two segments in the direction in which the first semiconductor base and the second semiconductor base extend (thirteenth aspect).

In the thirteenth aspect, the two segments of the split first gate conductor layer may be driven synchronously or asynchronously (fourteenth aspect).

### BRIEF DESCRIPTION OF THE DRAWINGS

FIG. 1 is a structural diagram of a memory device according to a first embodiment;

FIGS. 2A, 2B, and 2C illustrate the erase operation mechanism of the memory device according to the first embodiment;

FIGS. 3A, 3B, and 3C illustrate the write operation mechanism of the memory device according to the first embodiment;

FIGS. 4AA, 4AB, and 4AC illustrate the read operation mechanism of the memory device according to the first embodiment;

FIGS. 4BA, 4BB, 4BC, and 4BD illustrate the read operation mechanism of the memory device according to the first embodiment;

FIGS. 5AA, 5AB, and 5AC illustrate a method for manufacturing the memory device according to the first embodiment;

FIGS. 5BA, 5BB, and 5BC illustrate the method for manufacturing the memory device according to the first embodiment;

FIGS. 5CA, 5CB, and 5CC illustrate the method for manufacturing the memory device according to the first embodiment;

FIGS. 5DA, 5DB, and 5DC illustrate the method for manufacturing the memory device according to the first embodiment;

FIGS. 5EA, 5EB, and 5EC illustrate the method for manufacturing the memory device according to the first embodiment;

FIGS. 5FA, 5FB, and 5FC illustrate the method for manufacturing the memory device according to the first embodiment;

FIGS. 5GA, 5GB, and 5GC illustrate the method for manufacturing the memory device according to the first embodiment;

FIG. 5H illustrates the method for manufacturing the memory device according to the first embodiment;

FIGS. 6A, 6B, and 6C illustrate a method for manufacturing a memory device according to a second embodiment;

FIGS. 7A, 7B, and 7C illustrate a method for manufacturing a memory device according to a third embodiment;

FIGS. 8A, 8B, 8C, and 8D illustrate a problem with the operation of an example of a capacitorless DRAM memory cell in the related art;

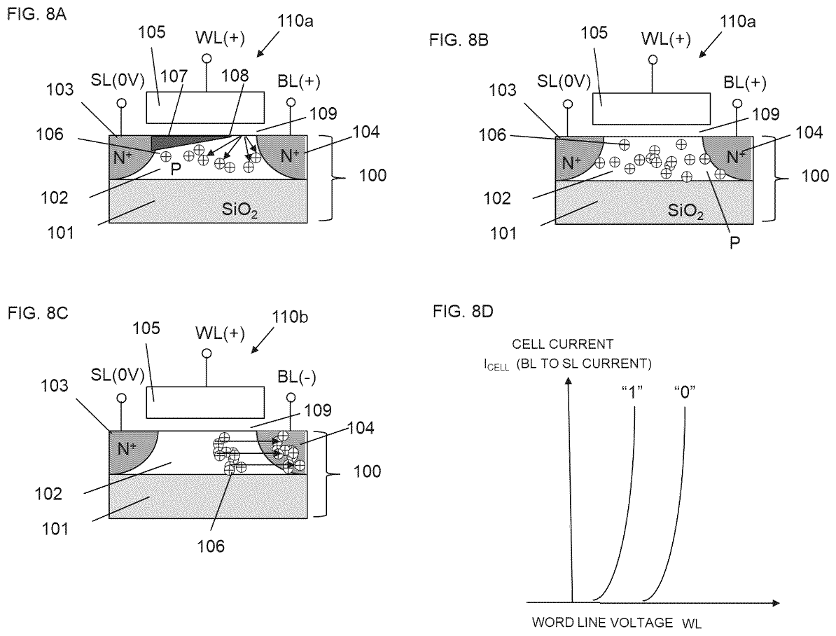

FIGS. 9A and 9B illustrate the problem with the operation of the capacitorless DRAM memory cell the related art; and

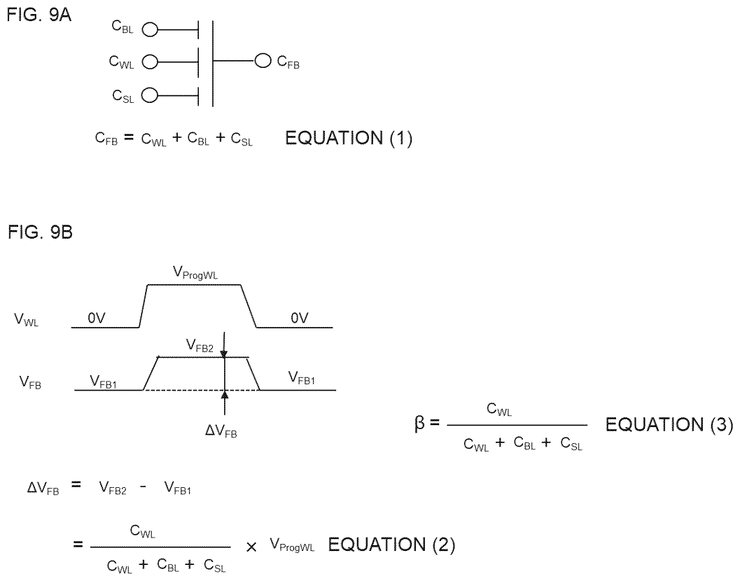

FIGS. 10A, 10B, and 10C illustrate the read operation of the capacitorless DRAM memory cell in the related art.

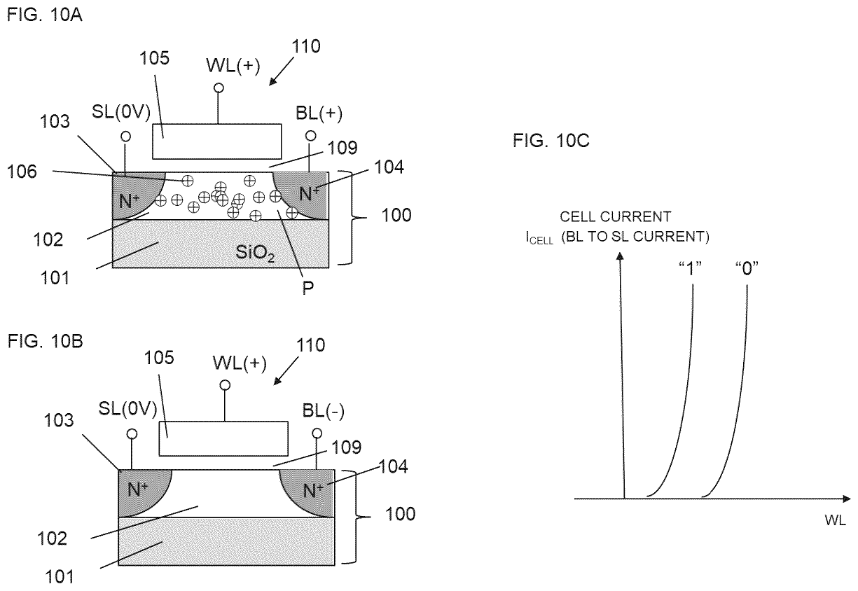

### DESCRIPTION OF THE PREFERRED EMBODIMENTS

The structures and methods of manufacture of memory devices including semiconductor elements (hereinafter referred to as “dynamic flash memory”) according to embodiments of the present invention will be described below with reference to the drawings.

### First Embodiment

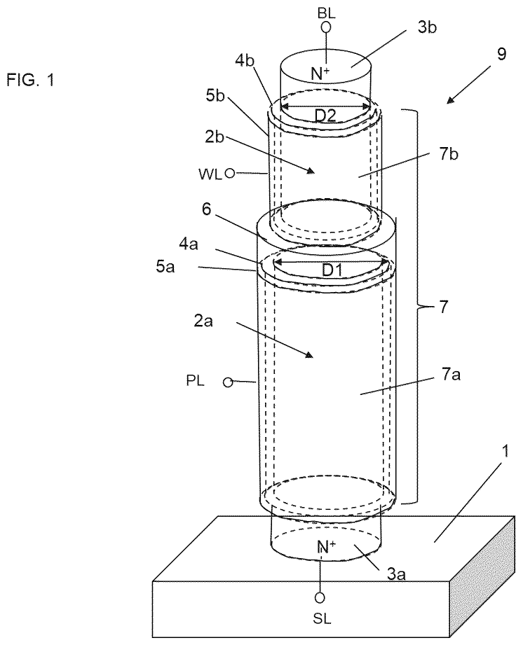

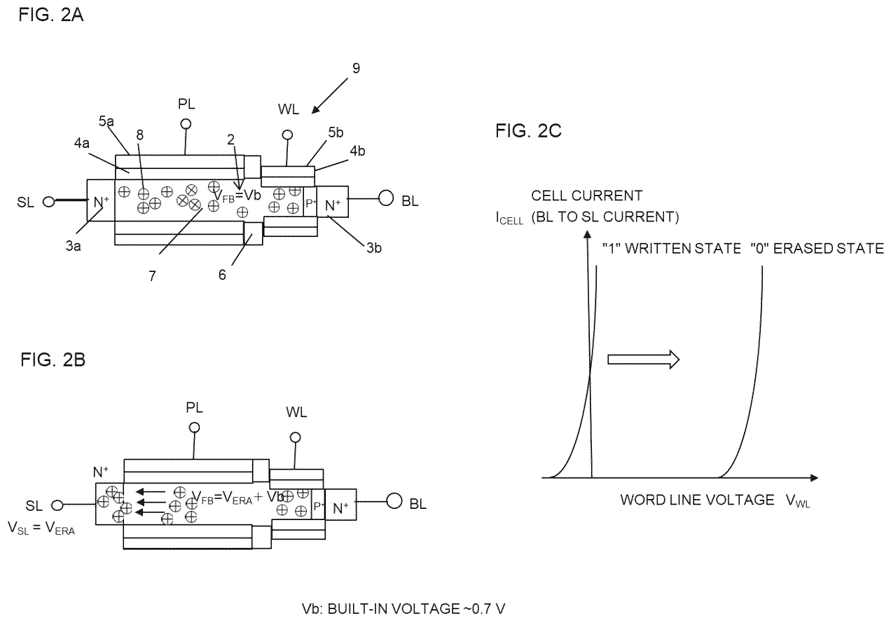

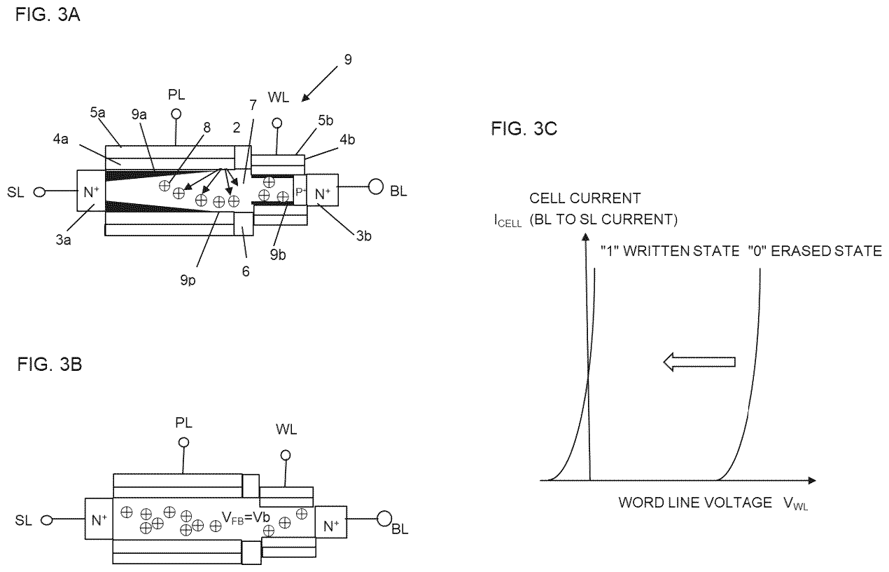

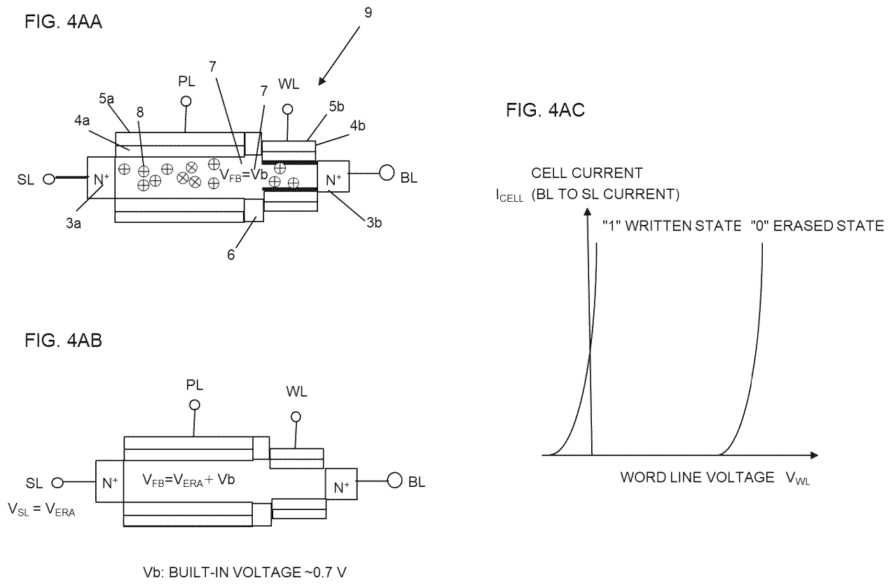

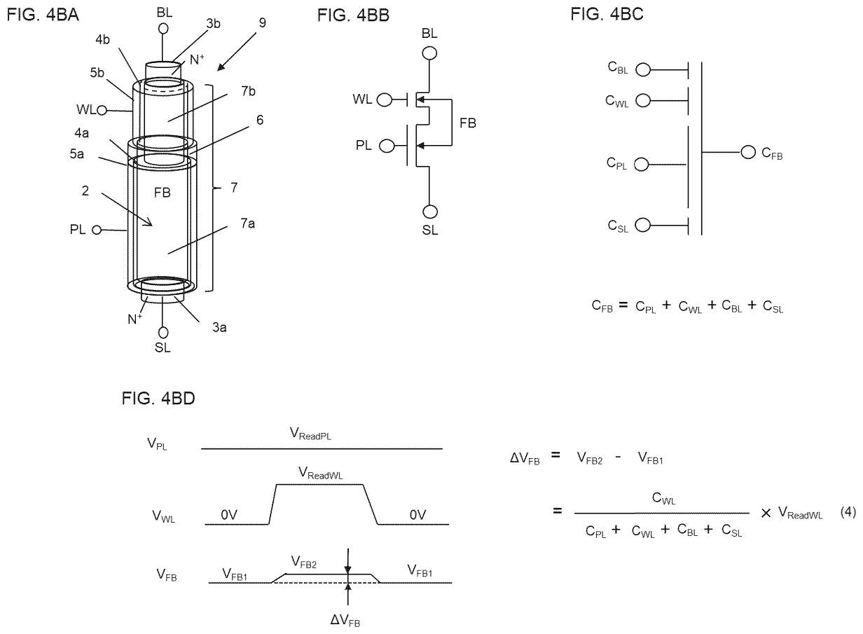

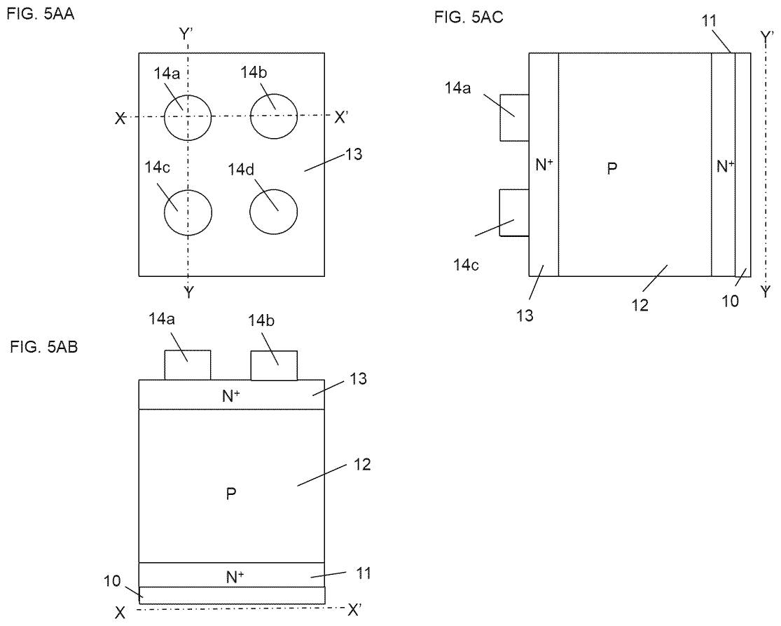

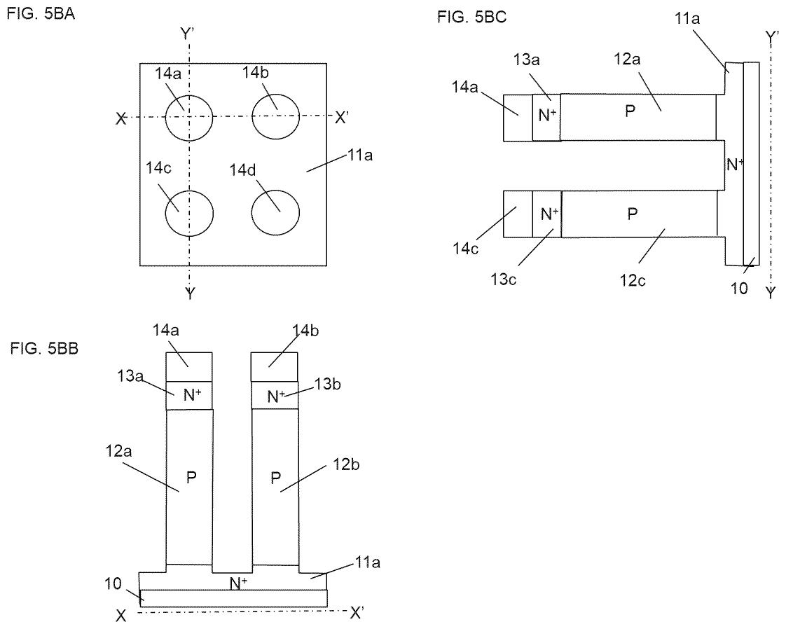

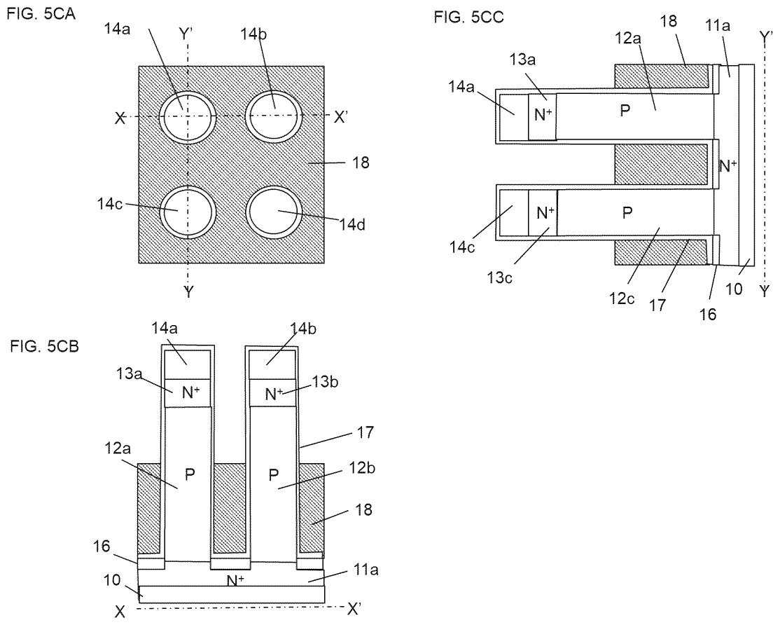

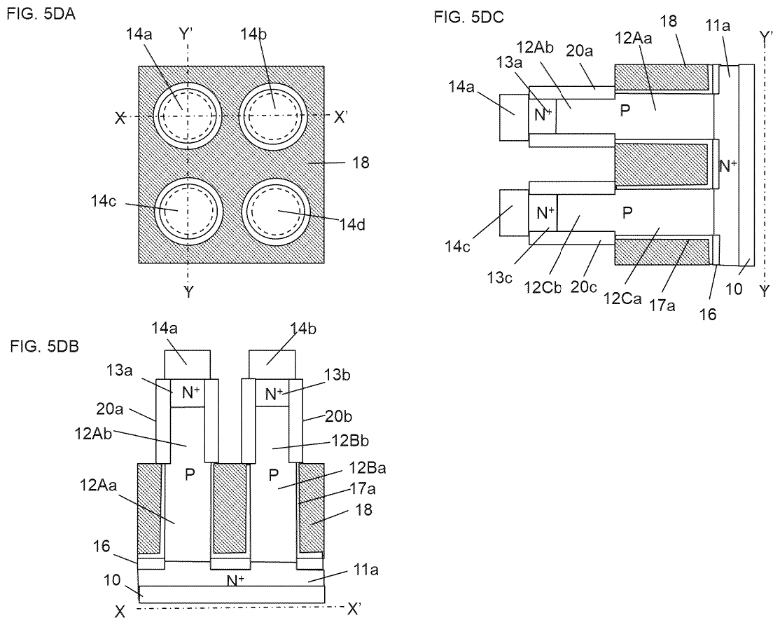

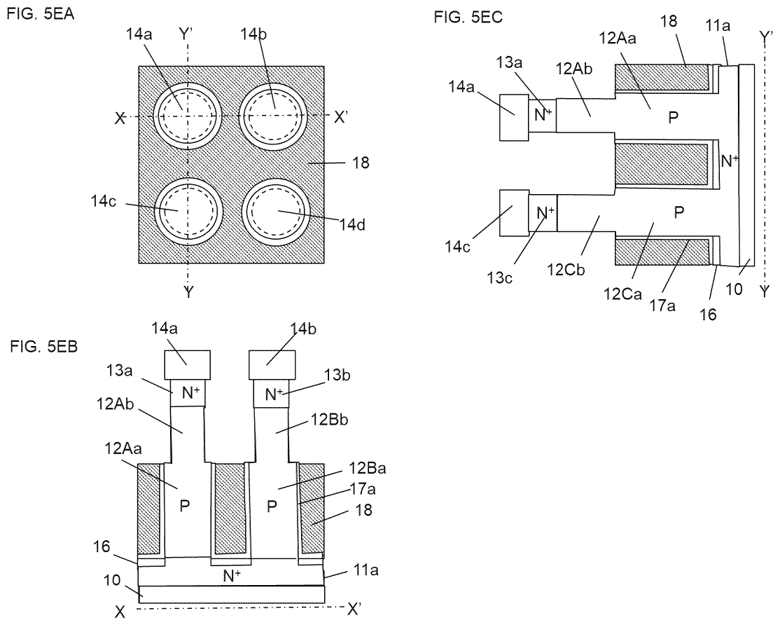

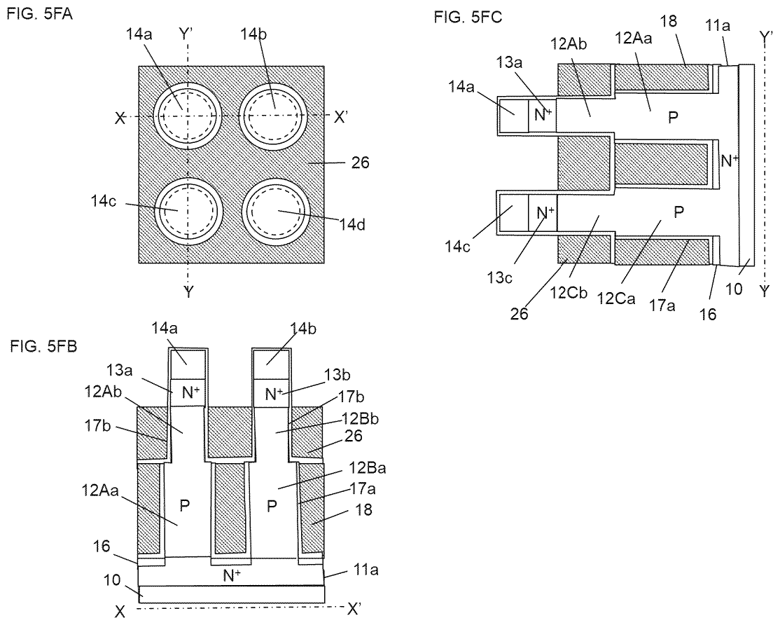

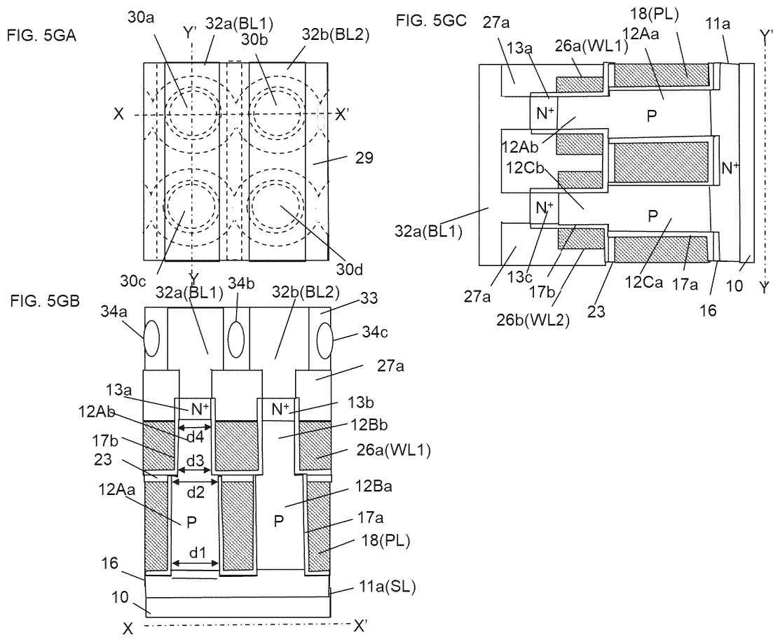

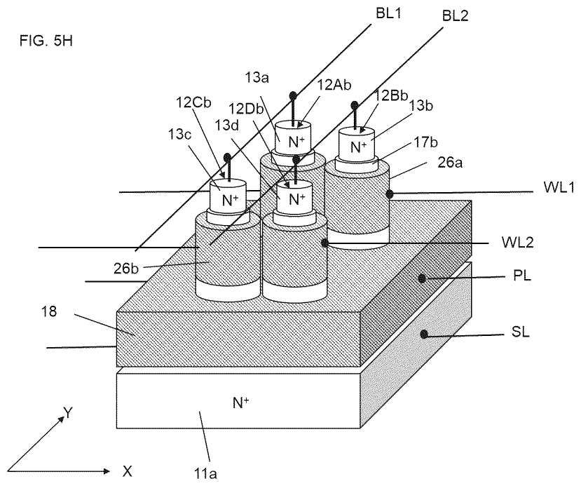

The structure, operating mechanism, and method of manufacture of a dynamic flash memory cell according to a first embodiment of the present invention will be described with reference to FIGS. 1 to 5H. The structure of the dynamic flash memory cell will be described with reference to FIG. 1. The data erase mechanism will be described with reference to FIGS. 2A, 2B and 2C. The data write mechanism will be described with reference to FIGS. 3A, 3B and 3C. The data read mechanism will be described with reference to FIGS. 4AA to 4BD. The method for manufacturing the dynamic flash memory will be described with reference to FIGS. 5AA to 5H.

FIG. 1 illustrates the structure of the dynamic flash memory cell according to the first embodiment of the present invention. A first silicon pillar 2a (an example of “first semiconductor base” in the claims) (a silicon pillar is hereinafter referred to as “Si pillar”) of P-type or i-type (intrinsic type) conductivity is disposed above a substrate 1 (an example of “substrate” in the clams), and a second Si pillar 2b (an example of “second semiconductor base” in the claims) is disposed on the first Si pillar 2a and is connected to the first Si pillar 2a. The diameter D1 of the first Si pillar 2a is greater than the diameter D2 of the second Si pillar 2b. That is, the cross-sectional area of the first Si pillar 2a is greater than the cross-sectional area of the second Si pillar 2b. An N⁺ layer 3a (an example of “first impurity region” in the claims) connected to the bottom portion of the first Si pillar 2a and an N⁺ layer 3b (an example of “second impurity region” in the claims) connected to the top portion of the second Si pillar 2b are also formed. One of the N⁺ layers 3a and 3b serves as a source when the other serves as a drain. The portion of the first Si pillar 2a and the second Si pillar 2b between the N⁺ layers 3a and 3b serving as the source and the drain serves as a channel region 7. A first gate insulating layer 4a (an example of “first gate insulating layer” in the claims) surrounding the first Si pillar 2a is formed, and a second gate insulating layer 4b (an example of “second gate insulating layer” in the claims) surrounding the second Si pillar 2b is formed. The first gate insulating layer 4a and the second gate insulating layer 4b are in contact with or in proximity to the N⁺ layers 3a and 3b, respectvely, serving as the source and the drain. A first gate conductor layer 5a (an example of “first gate conductor layer” in the claims) is formed so as to surround the first gate insulating layer 4a, and a second gate conductor layer 5b (an example of “second gate conductor layer” in the claims) is formed so as to surround the second gate insulating layer 4b. The first gate conductor layer 5a and the second gate conductor layer 5b are isolated from each other by an insulating layer 6. The channel region 7, which is the portion of the Si pillar 2 between the N⁺ layers 3a and 3b, includes a first channel region 7a formed of the first Si pillar 2a and surrounded by the first gate insulating layer 4a and a second channel region 7b formed of the second Si pillar 2b and surrounded by the second gate insulating layer 4b. Thus, a dynamic flash memory cell including the N⁺ layers 3a and 3b serving as the source and the drain, the channel region 7, the first gate insulating layer 4a, the second gate insulating layer 4b, the first gate conductor layer 5a, and the second gate conductor layer 5b is formed. The N⁺ layer 3a serving as the source is connected to a source line SL (an example of “source line” in the claims). The N⁺ layer 3b serving as the drain is connected to a bit line BL (an example of “bit line” in the claims). The first gate conductor layer 5a is connected to a plate line PL (an example of “first drive control line” in the claims). The second gate conductor layer 5b is connected to a word line WL (an example of “word line” in the claims). The first gate insulating layer 4a and the second gate insulating layer 4b may be formed as a single continuous insulating layer or may be separately formed. In addition, in plan view, the first gate insulating layer 4a may be formed so as to surround a portion or the entirety of the first Si pillar 2a, and the second gate insulating layer 4b may be formed so as to surround a portion or the entirety of the second Si pillar 2b.

In FIG. 1, the gate capacitance of the first gate conductor layer 5a is proportional to the surface area of the side surface of the first Si pillar 2a, and the gate capacitance of the second gate conductor layer 5b is proportional to the surface area of the side surface of the second Si pillar 2b. Therefore, when the diameter D1 of the first Si pillar 2a is greater than the diameter D2 of the second Si pillar 2b, the surface area of the side surface of the first Si pillar 2a is greater than the surface area of the side surface of the second Si pillar 2b even if the lengths of the first Si pillar 2a and the second Si pillar 2b in the perpendicular direction are equal. Thus, the gate capacitance of the first gate conductor layer 5a is greater than the gate capacitance of the second gate conductor layer 5b.

In addition, the gate capacitance of the first gate conductor layer 5a connected to the plate line PL can be made even greater than the gate capacitance of the second gate conductor layer 5b connected to the word line WL if the gate length of the first gate conductor layer 5a is longer than the gate length of the second gate conductor layer 5b so that the gate capacitance of the first gate conductor layer 5a is greater than the gate capacitance of the second gate conductor layer 5b. Alternatively, the gate capacitance of the first gate conductor layer 5a can be made even greater than the gate capacitance of the second gate conductor layer 5b if, in a structure in which the gate length of the first gate conductor layer 5a is longer or not longer than the gate length of the second gate conductor layer 5b, the thicknesses of the gate insulating layers 4a and 4b are varied so that the thickness of the gate insulating film forming the first gate insulating layer 4a is small than the thickness of the gate insulating film forming the second gate insulating layer 4b. The dielectric constants of the materials for the gate insulating layers 4a and 4b may also be varied so that the dielectric constant of the gate insulating film forming the first gate insulating layer 4a is higher than the dielectric constant of the gate insulating film forming the second gate insulating layer 4b. Any combination of the lengths of the gate conductor layers 5a and 5b, the thicknesses of the gate insulating layers 4a and 4b, and the dielectric constants of the gate insulating layers 4a and 4b may be varied so that the gate capacitance of the first gate conductor layer 5a is even greater than the gate capacitance of the second gate conductor layer 5b. In addition, the first gate conductor layer 5a may be split into two gate conductor layers in the perpendicular direction, and the two gate conductor layers may be electrically connected together around a memory block composed of a plurality of memory cells. In this case, it is desirable that the three gate conductor layers, namely, the two separate gate conductor layers and the second gate conductor layer 5b, have the same length in the perpendicular direction.

The data erase operation mechanism will be described with reference to FIGS. 2A, 2B and 2C. The channel region 7 between the N⁺ layers 3a and 3b is electrically isolated from the substrate 1, thus forming a floating body. FIG. 2A illustrates a state in which a group of holes 8 generated by impact ionization in the previous cycle are accumulated in the channel region 7 before the erase operation. As illustrated in FIG. 2B, during the erase operation, the voltage of the source line SL is set to a negative voltage V_{BRA}. Here, V_{EPA} is, for example, −3 V. As a result, irrespective of the value of the initial potential of the channel region 7, the PH junction between the N⁺ layer 3a serving as the source and having the source line SL connected thereto and the channel region 7 is forward-biased. As a result, the group of holes 8 generated by impact ionization in the previous cycle and accumulated in the channel region 7 are absorbed into the N⁺ layer 3a serving as the source portion, and the potential V_{FB} of the channel region 7 is V_{FB}=V_{BRA}+V_{b}. Here, Vb is the built-in voltage of the PN junction and is about 0.7 V. Hence, when V_{ERA}=−3 V, the potential of the channel region 7 is −2.3 V. This value represents the potential state of the channel region 7 in the erased state. Thus, when the potential of the channel region 7 of the floating body is a negative voltage, the threshold voltage of the N-channel MOS transistor of the dynamic flash memory cell 10 becomes higher under a substrate bias effect. Accordingly, as illustrated in FIG. 2C, the threshold voltage of the second gate conductor layer 5b having the word line WL connected thereto becomes higher. The erased state of the channel region 7 is logic storage data “0”. By setting the voltage applied to the first gate conductor layer 5a connected to the plate line PL to higher than the threshold voltage for logic storage data “1” and lower than the threshold voltage for logic storage data “0” in data reading, the property of not allowing a current to flow when the voltage of the word line WL is increased during reading of logic storage data “0” can be achieved. The above conditions for the voltages applied to the bit line BL, the source line SL, the word line WL, and the plate line PL are example conditions for performing the data erase operation and may be other operational conditions where the data erase operation can be performed. For example, the data erase operation may be performed with a voltage difference between the bit line BL and the source line SL.

FIGS. 3A, 3B and 3C illustrate the write operation of the dynamic flash memory cell according to the first embodiment of the present invention. As illustrated in FIG. 3A, a voltage of, for example, 0 V is input to the N⁺ layer 3a having the source line SL connected thereto, a voltage of, for example, 3 V is input to the N⁺ layer 3b having the bit line BL connected thereto, a voltage of, for example, 2 V is input to the first gate conductor layer 5a having the plate line PL connected thereto, and a voltage of, for example, 5 V is input to the second gate conductor layer 5b having the word line WL connected thereto. As a result, as illustrated in FIG. 3A, an inversion layer 9a is formed inside the first gate conductor layer 5a having the plate line PL connected thereto, and a first N-channel MOS transistor region formed by the first channel region 7a surrounded by the first gate conductor layer 5a is operated in the saturation region. As a result, a pinch-off point 9p is present in the inversion layer 9a inside the first gate conductor layer 5a having the plate line PL connected thereto. On the other hand, a second N-channel MOS transistor region formed by The second channel region 7b surrounded by the second gate conductor layer 5b having the word line WL connected thereto is operated in the linear region. As a result, an inversion layer 9b is formed without a pinch-off point over the entire surface inside the second gate conductor layer 5b having the word line WL connected thereto. The inversion layer 9b formed over the entire surface inside the second gate conductor layer 5b having the word line WL connected thereto functions as a virtual drain of the second N-channel MOS transistor region. As a result, the maximum electric field intensity is reached in a first boundary region of the, channel region 7 between the first N-channel MOS transistor region, having the first gate conductor layer 5a, and the second N-channel MOS transistor region, having the second gate conductor layer 5b, that are series-connected, and an impact ionization phenomenon occurs in this region. This impact ionization phenomenon causes electrons to flow from the N⁺ layer 3a having the source line SL connected thereto toward the N⁺ layer 3b having the bit line BL connected thereto. The accelerated electrons collide with the lattice Si atoms, the kinetic energy thereof generates electron-hole pairs. While some of the generated electrons flow into the first gate conductor layer 5a and the second gate conductor layer 5b, most of the electrons flow into the N⁺ layer 3b having the bit line BL connected thereto. In “1” writing, a gate-induced drain leakage (GIDL) current may also be used to generate electron-hole pairs and fill the floating body FB with the group of generated holes (see E. Yoshida, and T. Tanaka: “A Capacitoriess 1T-DRAM Technology Using Gate-Induced Drain-Leakage (GIDL) Current for Low-Power and High-Speed Embedded Memory,” IEEE Transactions on Electron Devices, Vol. 53, No. 4, pp. 692-697, April 2006). The generation of electron-hole pairs by the impact ionization phenomenon can also be performed in a second boundary region between the N⁺ layer 3a and the channel region 7 or in a third boundary region between the N⁺ layer 3b and the channel region 7.

As illustrated in FIG. 3B, the group of generated holes 8 are majority carriers in the channel region 7 and charge the channel region 7 to a positive bias. Because the voltage of the N⁺ layer 3a having the source line SL connected thereto is 0 V, the channel region 7 is charged to the built-in voltage Vb (about 0.7 V) of the PN junction between the N⁺ layer 3a having the source line SL connected thereto and the channel region 7. When the channel region 7 is charged to a positive bias, the threshold voltage of the first N-channel MOS transistor region and the second N-channel MOS transistor region becomes lower under a substrate bias effect. Thus, as illustrated in FIG. 3C, the threshold voltage of the N-channel MOS transistor of the second channel region 7b having the word line WL connected thereto becomes lower. This written state of the channel region 7 is assigned to logic storage data “1”.

In the data write operation, electron-hole pairs may also be generated by an impact ionization phenomenon or a GIDL current in a second boundary region between the first impurity region and the first semiconductor base or in a third boundary region between the second impurity region and the second semiconductor base, rather than in the first boundary region, and the channel region 7 may be charged with the group of generated holes. The above conditions for the voltages applied to the bit line BL, the source line SL, the word line WL, and the plate line PL are example conditions for performing the data write operation and may be other operational conditions where the data write operation can be performed.

The data read operation of the dynamic flash memory cell according to The first embodiment of the present invention and the related memory cell structure will be described with reference to FIGS. 4AA to 4BD. The read operation of the dynamic flash memory cell will be described with reference to FIGS. 4AA, 4AB and 4AC. As illustrated in FIG. 4AA, when the channel region 7 is charged to the built-in voltage Vb (about 0.7 V), the threshold voltage of the N-channel MOS transistor decreases under a substrate bias effect. This state is assigned to logic storage data “1”. As illustrated in FIG. 4AB, when the memory block selected before writing is in the erased state “0” in advance, the floating voltage V_{FB} of the channel region 7 is V_{ERA}+Vb. The written state “1” is randomly stored by a write operation. As a result, logic storage data representing logic “0” and logic “1” is created for the word line WL. As illustrated in FIG. 4AC, the difference between the two threshold voltages for the word line WL is utilized for data reading by a sense amplifier.

The magnitude relationship between the gate capacitances of the first gate conductor layer 5a and the second gate conductor layer 5b and the related operation during the data read operation of the dynamic flash memory cell according to the first embodiment of the present invention will be described with reference to FIGS. 4BA to 4BD. It is desirable that the memory cell be designed such that the gate capacitance of the second gate conductor layer 5b having the word line WL connected thereto is smaller than the gate capacitance of the first gate conductor layer 5a having the plate line PL connected thereto. As illustrated in FIG. 4BA, the length of the first gate conductor layer 5a having the plate line PL connected thereto in the perpendicular direction is longer than the length of the second gate conductor layer 5b having the word line WL connected thereto in the perpendicular direction so that the gate capacitance of the second gate conductor layer 5b having the word line WL connected thereto is smaller than the gate capacitance of the first gate conductor layer 5a having the plate line PL connected thereto. FIG. 4BB illustrates an equivalent circuit of one cell of the dynamic flash memory in FIG. 4BA. FIG. 4BC illustrates the coupling capacitance relationship of the dynamic flash memory. Here, C_{WL} is the capacitance of the second gate conductor layer 5b, C_{PL} is the capacitance of the first gate conductor layer 5a, C_{BL} is the capacitance of the PN junction between the N⁺ layer 3b serving as the drain and the second channel region 7b, and C_{SL} is the capacitance of the PN junction between the N⁺ layer 3a serving as the source and the first channel region 7a. As illustrated in FIG. 4BD, as the voltage of the word line WL oscillates, its operation affects the channel region 7 as noise. The potential variation ΔV_{FB} in the channel region 7 in this case is as follows:

ΔV_{FB}=C_{WL}/(C_{PL}+C_{WL}+C_{BL}+C_{SL})×V_{ReadWL} (4)

where V_{ReadWL} is the oscillation potential of the word line WL during reading. As is obvious from equation (4), it can be understood that ΔV_{FB} becomes smaller as the contribution ratio of C_{WL} becomes smaller relative to the total capacitance of the channel region 7, i.e., C_{PL}+C_{WL}+C_{BL}+C_{SL}. To increase C_{BL}+C_{SL}, which is the capacitance of the PN junctions, for example, the diameter of the Si pillar 2 may be increased. This, however, is undesirable for miniaturization of memory cells. In contrast, if the length of the first gate conductor layer 5a having the plate line PL connected thereto in the perpendicular direction is longer than the length of the second gate conductor layer 5b having the word line WL connected thereto in the perpendicular direction, ΔV_{FB} can be further reduced without decreasing the degree of integration of memory cells in plan view. The above conditions for the voltages applied to the bit line BL, the source line SL, the word line WL, and the plate line PL are example conditions for performing the data read operation and may be other operational conditions where the data read operation can be performed. The data read operation may also be performed using bipolar operation.

In addition, in FIG. 1, one or both of the first gate conductor layer 5a and the second gate conductor layer 5b may be split into two segments in plan view. In addition, one or both of the first gate conductor layer 5a and the second gate conductor layer 5b may be split into two or a plurality of segments in the perpendicular direction. The segments of the split first gate conductor layer 5a or second gate conductor layer 5b may be driven synchronously or asynchronously. This also allows normal memory operation.

In addition, in FIG. 1, when the second gate conductor layer 5b is split into two segments in the perpendicular direction, the lower gate conductor layer may operate as a plate line, whereas the upper gate conductor layer may operate as a word line. In this case, the first gate conductor layer 5a may operate as a second word line. In addition, when the first gate conductor layer 5a is split into two segments in the perpendicular direction, the upper gate conductor layer may operate as a plate line, whereas the lower gate conductor layer may operate as a second word line. This also allows normal memory operation.

A method for manufacturing the dynamic flash memory according to this embodiment will be described with reference to FIGS. 5AA to 5H. FIGS. 5AA, 5BA, 5CA, 5DA, 5EA, 5FA, and 5GA illustrate plan views. FIGS. 5AB, 5BB, 5CB, 5DB, 5EB, 5FB, and 5GB illustrate sectional views taken along lines X-X′ of FIGS. 5AA, 5BA, 5CA, 5DA, 5EA, 5FA, and 5GA, respectively. FIGS. 5AC, 5BC, 5CC, 5DC, 5EC, 5FC, and 5GC illustrate sectional views taken along lines Y-Y′ of FIGS. 5AA, 5BA, 5CA, 5DA, 5EA, 5FA, and 5GA, respectively.

As illustrated in FIGS. 5AA, 5AB and 5AC, in order from bottom, an N⁺ layer 11, a P layer 12 made of Si, and an N⁺ layer 13 are formed above a substrate 10. Mask material layers 14a, 14b, 14c, and 14d that are circular in plan view are then formed. The substrate 10 may be a silicon-on-insulator (SOI) substrate or may be composed of a single layer or a plurality of layers of Si or other semiconductor materials. The substrate 10 may also be a well layer composed of a single layer or a plurality of layers of N type or P type.

Next, as illustrated in FIGS. 5BA, 5BB and 5BC, the N⁺ layer 13, the P layer 12, and the upper portion of the N⁺ layer 11 are etched using the mask material layers 14a to 14d as a mask to form Si pillars 12a, 12b, 12c, and 12d (not illustrated) and N⁺ layers 13a, 13b, 13c, and 13d (not illustrated) above an N⁺ layer 11a.

Next, as illustrated in FIGS. 5CA, 5CB and 5CC, a HfO₂ layer 17 serving as a gate insulating layer is formed over the entire surface, for example, by atomic layer deposition (ALD). A TiN layer (not illustrated) serving as a gate conductor layer is then formed over the entire surface. The TiN layer is then polished by chemical mechanical polishing (CMP) such that the upper surface thereof is located at the upper surfaces of the mask material layers 14a to 14d. The TiN layer is then etched by reactive ion etching (RIE) such that the upper surface thereof is located near the midpoints of the Si pillars 12a to 12d in the perpendicular direction to form a TiN layer 18. The HfO₂ layer 17 may be replaced by another insulating layer composed of a single layer or a plurality of layers as long as the insulating layer functions as a gate insulating layer. The TiN layer 18 may also be replaced by another conductor layer composed of a single layer or a plurality of layers as long as the conductor layer functions as a gate conductor layer. A protective layer or a wiring layer such as a TaN layer or a W layer may be formed outside the TiN layer 18. In addition, it is desirable to etch the TiN layer 18 such that the upper surface thereof is located above the midpoints of the Si pillars 12a to 12d in the perpendicular direction.

Next, the portion of the HfO₂ layer 17 above the upper surface of the TiN layer 18 in the perpendicular direction is removed to form a HfO₂ layer 17a. As illustrated in FIGS. 5DA, 5DB and 5DC, the exposed side surfaces of the Si pillars 12a to 12d are oxidized to form SiO₂ layers 20a, 20b, 20c, and 20d (not illustrated). As the exposed Si surfaces of the Si pillars 12a to 12d are oxidized, Si pillars 12Ab, 12Bb, 12Cb, and 12Db (not illustrated) having a smaller parallel cross-section than the Si pillars 12a to 12d are formed. Si pillars 12Aa, 12Ba, l2Ca, and 12Da (not illustrated) below the Si pillars 12Ab to 12Db have the same cross-sectional shape as the original Si pillars 12a to 12d.

Next, as illustrated in FIGS. 5EA, 5EB and 5EC, the SiO₂ layers 20a to 20d are removed to expose the side surfaces of the Si pillars 12Ab, 12Bb, 12Cb, and 12Db and the side surfaces of the N⁺ layers 13a to 13d.

Next, as illustrated in FIGS. 5FA, 5FB and 5FC, a HfO₂ layer 17b is formed over the entire surface. A TiN layer 26 is then formed so as to surround the HfO₂ layer 17b such that the upper surface thereof is located near the lower ends of the N⁺ layers 13a to 13d. The planar shape of the mask material layers 14a to 14d becomes smaller as the surface layer is etched during cleaning before the formation of the HfO₂ layer 17b.

Next, as illustrated in FIGS. 5GA, 5GB and 5GC, a TiN layer 26a extending between the Si pillars 12Ab and 12Bb and a TiN layer 26b extending between the Si pillars 12Cb and 12Db are formed so as to surround the side surfaces of the HfO₂ layer 17b. The TiN layer 26a is formed so as to extend between the Si pillars 12Ab and 12Bb and to be separated from the TiN layer 26b between the Si pillars 12Ab and 12Cb. Similarly, the TiN layer 26b is formed so as to extend between the Si pillars 12Cb and 12Db and to be separated from the TiN layer 26a between the Si pillars 12Bb and 12Db. A SiN layer 27a is then formed so as to surround the side surfaces of the N⁺ layers 13a to 13d and the mask material layers 14a to 14d. The mask material layers 14a to 14d are then removed by etching using the SiN layer 27a as a mask. A bit line BL1 conductor layer 32a connected to the N⁺ layers 13a and 13c and a bit line BL2 conductor layer 32b connected to the N⁺ layers 13b and 13d are then formed. A SiO₂ layer 33 is then formed so as to surround the bit line BL1 conductor layer 32a and the bit line BL2 conductor layer 32b and to include voids 34a, 34b, and 34c extending in the direction along line Y-Y′.

Thus, a dynamic flash memory is formed on the substrate 10. The TiN layers 26a and 26b serve as word line conductor layers WL1 and WL2, the TiN layer 18 serves as a plate line conductor layer PL that also serves as a gate conductor layer, and the N⁺ layer 11a serves as a source line conductor layer SL that also serves as a source impurity layer.

As illustrated in FIGS. 5GA, 5GB and 5GC, the diameter d3 of the bottom portions of the Si pillars 12Ab to 12Db and the diameter d4 of the top portions of the Si pillars 12Ab to 12Db are smaller than the diameter d2 of the top portions of the Si pillar 12Aa to 12Da. The diameter d1 of the bottom portions of the Si pillars 12Aa to 12Da are greater than or equal to the diameter d2 of the top portions of the Si liars 12Aa to 12Da. This means that, in plan view, the outer periphery lines of the second Si pillars 12Ab to Db are located within the outer periphery lines of the top portions of the corresponding first Si pillars 12Aa to 12Da.

FIG. 5H illustrates a schematic structural diagram of the dynamic flash memory illustrated in FIGS. 5GA, 5GB and 5GC. The N⁺ layer 11a serving as the source line conductor layer SL is formed so as to extend over the entire surface. The plate line conductor layer PL is also formed so as to extend over the entire surface. The gate conductor TiN layer 26a connected to the word line conductor layer WL1 is formed so as to extend between the adjacent Si pillars 12Ab and 12Bb in the X direction. Similarly, the gate conductor TiN layer 26b connected to the word line conductor layer WL2 is formed so as to extend between the adjacent Si pillars 12Cb and 12Db in the X direction. The bit line conductor layer BL1 connected to the N⁺ layers 13a and 13c and the bit line conductor layer BL2 connected to the N⁺ layers 13b and 13d are formed in the Y direction orthogonal to the X direction.

In addition, in FIGS. 5AA to 5H, the Si pillars 12a to 12d are formed by etching the P layer 12 using the mask material layers 14a to 14d as an etching mask. Alternatively, for example, a plurality of material layers may be deposited and etched to form holes, and the holes may be filled with a Si layer to form the Si pillars 12a to 12d, for example, by a selective epitaxial crystal growth process.

The dynamic flash memory operation described in this embodiment can also be achieved if the parallel cross-sections of the first Si pillar 2a and the second Si pillar 2b in FIG. 1 are circular, oval, or rectangular. In addition, circular, oval, and rectangular dynamic flash memory cells may coexist on the same chip. In this case, the gate capacitance of the first gate conductor layer 5a is greater than the gate capacitance of the second gate conductor layer 5b if the condition that the outer periphery line of the second Si pillar 2b in a parallel cross-section is located within the outer periphery line of the top portion of the first Si pillar 2a in a parallel cross-section is satisfied.

In FIG. 1, a dynamic flash memory element has been described using as an example an SGT including the first gate insulating layer 4a and the second gate insulating layer 4b surrounding the entire side surfaces of the first Si pillar 2a and the second Si pillar 2b standing above the substrate 1 in the perpendicular direction and the first gate conductor layer 5a and the second gate conductor layer 5b surrounding the first gate insulating layer 4a and the second gate insulating layer 4b in their entirety. As illustrated in this embodiment, it is sufficient that the dynamic flash memory element have a structure satisfying the condition that a group of holes generated by an impact ionization phenomenon or a gate-induced drain leakage current are held in the channel region 7. Accordingly, it is sufficient that the channel region 7 have a floating body structure isolated from the substrate 1. Thus, the dynamic flash memory operation described above can also be achieved if the semiconductor base forming the channel region is formed parallel to the substrate 1, for example, using gate-all-around technology (GAA; see, for example, J. Y. Song, W. Y. Choi, J. H. Park, J. D. Lee, and B-G. Park: “Design Optimization of Gate-All-Around (GAA) MOSFETs,” IEEE Trans. Electron Devices, Vol. 5, No. 3, pp. 186-191, May 2006) or nanosheet technology (see, for example, N. Loubet, et. al.: “Stacked Nanosheet Gate-All-Around Transistor to Enable Scaling Beyond FinFET,” 2017 IEEE Symposium on VLSI

Technology Digest of Technical Papers, T17-5, T230-T231, June 2017), each of which is a type of SGT. In addition, the device structure may be one using a silicon-on-insulator (SOI) substrate (see, for example, J. Wan, L. Rojer, A. Zaslavsky, and S. Critoloveanu: “A Compact Capacitor-Less High-Speed DRAM Using Field Effect-Controlled Charge Regeneration,” Electron Device Letters, Vol. 35, No. 2, pp. 179-181 (2012); T. Ohsawa, K. Fujita, T. Higashi, Y. Iwata, T. Kajiyama, Y. Asao, and K. Sunouchi: “Memory design using a one-transistor gain cell on SOI,” IEEE JSSC, Vol. 37, No. 11, pp. 1510-1522 (2002); T. Shino, N. Kusunoki, T. Higashi, T. Ohsawa, K. Fujita, K. Hatsuda, N. Ikumi, F. Matsuoka, Y. Kajitani, R. Fukuda, Y. Watanabe, Y. Minami, A. Sakamoto, J. Nishimura, H. Nakajima, Morikado, K. Inch, T. Hamamoto, and A. Nitayama: “Floating Body RAM Technology and its Scalabilty to 32 nm Node and Beyond,” IEEE TEDM (2006); and E. Yoshida and T. Tanaka: “A Design of a Capacitorless 1T-DRAM Cell Using Gate-Induced Drain-Leakage (GIDL Current for Low-Power and High-Speed Embedded Memory,” IEEE IEDM (2003)). In this device structure, the bottom portion of the channel region is in contact with the insulating layer of the SOI substrate, and the remaining channel region is surrounded by a gate insulating layer and an element isolation insulating layer. This structure also allows the channel region to have a floating body structure. Thus, it is sufficient that the dynamic flash memory element provided by this embodiment satisfy the condition that the channel region has a floating body structure. The dynamic flash memory operation can also be achieved using a structure in which a fin transistor (see, for example, H. Jiang, N. Xu, B. Chen, L. Zeng, Y. He, G. Du, X. Liu, and K. Zhang: “Experimental investigation of self heating effect (SHE) in multiple-fin SOI FinFETs,” Semicond. Sci. Technol. 29 (2014) 115021 (7 pp)) is formed on an SOI substrate as long as the channel region has a floating body structure.

In FIG. 1, the potential distributions of the first channel region 7a and the second channel region 7b are formed so as to be connected together in the portion of the channel region 7 surrounded by the insulating layer 6 in the perpendicular direction. Thus, the first channel region 7a and the second channel region 7b are connected together in the region of the channel region 7 surrounded by the insulating layer 6 in the perpendicular direction.

As illustrated in FIGS. 5GA, 5GB and 5GC, the N⁻ layer 11a also serves as a wiring conductor layer for the source line SL. Alternatively, a conductor layer, such as a W layer, formed between N⁻ layers 11a under the bottom portions of the Si pillars 12a to 12d and may be used as the source line SL. A conductor layer such as a W layer may also be formed on the N⁺ layer 11a outside a region in which many Si pillars 12a to 12d are two-dimensionally formed.

In FIGS. 5DA, 5DB and 5DC, the second Si pillars 12Ab, 12Bb, 12Cb, and 12Db are formed by removing the SiO₂ layers 20a to 20d formed by oxidizing the exposed side surfaces of the Si pillars 12a to 12d. Alternatively, the second Si pillars 12Ab, 12Bb, 12Cb, and 12Db may be formed by directly etching the exposed side surfaces. Other methods may also be employed.

This embodiment provides the following features.

### Feature 1

In the dynamic flash memory cell according to the first embodiment of the present invention, the plate line PL functions to reduce the capacitive coupling ratio between the word line WL and the channel region 7 when the voltage of the word line WL oscillates up and down during the write or read operation of the dynamic flash memory cell. As a result, the effect of the change in the voltage of the channel region 7 that occurs when the voltage of the word line WL oscillates up and down can be considerably reduced. Thus, the difference between the SGT transistor threshold voltages of the word line WL that represent logic “0” and logic “1” can be increased. This leads to a broader margin of operation of the dynamic flash memory cell.

### Feature 2

In FIG. 1, the gate capacitance of the first gate conductor layer 5a is proportional to the surface area of the side surface of the first Si pillar 2a, and the gate capacitance of the second gate conductor layer 5b is proportional to the surface area of the side surface of the second Si pillar 2b. Because the first Si pillar 2a and the second Si pillar 2b are formed such that, in plan view, the outer periphery line of the first Si pillar 2a is located outside the outer periphery line of the second Si pillar 2b, the surface area of the side surface of the first Si pillar 2a is greater than the surface area of the side surface of the second Si pillar 2b. Thus, the gate capacitance of the first gate conductor layer 5a can be made greater than the gate capacitance of the second gate conductor layer 5b. This contributes to a broader margin of operation of the dynamic flash memory cell.

### Feature 3

Because the height of the first Si pillar 2a is greater than the height of the second Si pillar 2b in FIG. 1, the gate capacitance of the first gate conductor layer 5a can be made even greater than the gate capacitance of the second gate conductor layer 5b. This contributes to an even broader margin of operation of the dynamic flash memory cell.

### Second Embodiment

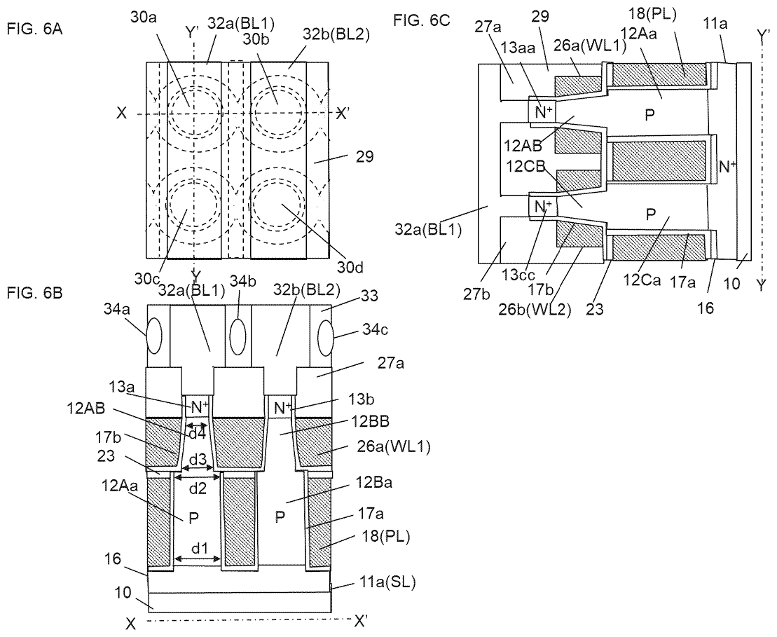

A dynamic flash memory according to a second embodiment will be described with reference to FIGS. 6A, 6B and 6C. FIG. 6A illustrates a plan view. FIG. 6B illustrates a sectional view taken along line X-X′ of FIG. 6A. FIG. 6C illustrates a sectional view taken along line Y-Y′ of FIG. 6A.

In the second embodiment, as illustrated in FIGS. 6A, 6B and 6C, a second Si pillar 12AB having a trapezoidal perpendicular cross-section is formed on the first Si pillar 12Aa. Similarly, second Si pillars 12BB, 12CB, and 12DB (not illustrated) having a trapezoidal perpendicular cross-section are formed on the first Si pillars 12Ba, 12Ca, and 12Da (not illustrated), respectively. Other details are substantially identical to those of the first embodiment described with reference to FIGS. 5AA to 5H. Thus, a dynamic flash memory is formed on the substrate 10.

This embodiment provides the following feature.

The diameter d3 of the bottom portions of the Si pillars 12AB to 12DB is greater than the diameter d4 of the top portions of the Si pillars 12AB to 12DB. The diameter d3 of the bottom portions of the Si pillars 12AB to 12DB is smaller than or equal to the diameter d2 of the top portions of the Si pillars 12Aa to 12Da. That is, the cross-sectional area of the bottom portions of the Si pillars 12AB to 12DB is greater than the cross-sectional area of the top portions of the Si pillars 12AB to 12DB. The cross-sectional area of the bottom portions of the Si pillars 12AB to 12DB is smaller than or equal to the cross-sectional area of the top portions of the Si pillars 12Aa to 12Da. This allows a larger proportion of the group of holes held in the second Si pillars 12AB to 12DB to be present on the bottom side thereof. Thus, leakage of the group of holes to adjacent memory cells due to external noise through the bit lines BL1 and BL2 can be reduced.

### Third Embodiment

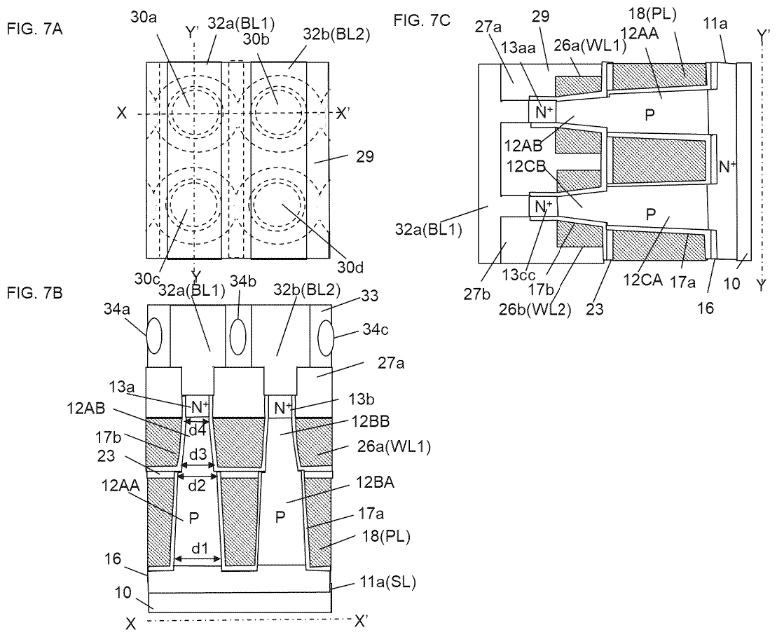

A dynamic flash memory according to a third embodiment will be described with reference to FIGS. 7A, 7B and 7C. FIG. 7A illustrates a plan view. FIG. 7B illustrates a sectional view taken along line X-X′ of FIG. 7A. FIG. 7C illustrates a sectional view taken along line Y-Y′ of FIG. 7A.

In the third embodiment, as illustrated in FIGS. 7A, 7B and 7C, a second Si pillar 12AB having a trapezoidal perpendicular cross-section is formed on a first Si pillar 12AA having a trapezoidal perpendicular cross-section. Similarly, second Si pillars 12BB, 12CB, and 12DB (not illustrated) having a trapezoidal perpendicular cross-section are formed on first Si pillars 12BA, 12CA, and 12DA (not illustrated), respectively, having a trapezoidal perpendicular cross-section. Other details are substantially identical to those of the first embodiment described with reference to FIGS. 5AA to 5H. Thus, a dynamic flash memory is formed on the substrate 10.

This embodiment provides the following feature.

The diameter d1 of the bottom portions of the first Si pillars 12AA to 12DA is greater than the diameter d2 of the top portions of the first Si pillars 12AA to 12DA. Therefore, during an operation of discharging a group of holes through the N⁻ layer 16 connected to the source line SL, the potential distributions in the first Si pillars 12AA to 12DA in the perpendicular direction are lower in the bottom portions thereof than in the top portions thereof, thus facilitating discharge of the group of holes. This results in a faster erase operation.

### Other Embodiments

Although the Si pillars 2 and 12a to 12d are formed in the embodiments of the present invention, semiconductor pillars made of other semiconductor materials may also be formed. This also applies to other embodiments according to the present invention.

In addition, the N⁺ layers 3a, 3b, 11, and 13 in the first embodiment may be formed of Si containing a donor impurity or other semiconductor materials. In addition, the N⁺ layers 3a, 3b, 11, and 13 may be formed of different semiconductor materials. In addition, the N⁺ layers 3a, 3b, 11, and 13 may be formed by an epitaxial crystal growth process or other processes. This also applies to other embodiments according to the present invention.

In addition, the TiN layer 18 is used as the plate line PL and the gate conductor layer 5a connected to the plate line PL in the first embodiment. Alternatively, the TiN layer 18 may be replaced by a single conductive material layer or a combination of a plurality of conductive material layers. Similarly, the TiN layers 26a and 26b are used as the word line WL and the gate conductor layer 5b connected to the word line WL. Alternatively, the TiN layers 26a and 26b may be replaced by a single conductive material layer or a combination of a plurality of conductive material layers. In addition, the gate TiN layers may have the outside thereof connected to a wiring metal layer such as a W layer. This also applies to other embodiments according to The present invention.

In addition, the shape of the Si pillars 12a to 12d in plan view is circular in the first embodiment. The shape of the Si pillars 12a to 12d in plan view may also be, for example, circular, oval, or elongated in one direction. In addition, Si pillars having different shapes in plan view can be formed in a logic circuit region formed away from the dynamic flash memory cell region, depending on the logic circuit design. These also apply to other embodiments according to the present invention.

In addition, in FIGS. 5AA to 5H, the N⁺ layer 11a connected to the bottom portions of the Si pillars 12a to 12d is formed. For example, a low-resistance conductor layer such as a W layer may be disposed on the N⁻ layer 11a around the outer peripheries of the Si pillars 12a to 12d. In addition, the portions of the N⁺ layer 11a under the Si pillars 12a and 12c may be electrically isolated from the portions of the N⁺ layer 11a under the Si pillars 12b and 12d, for example, using shallow trench isolation (STI) or a well structure, so that they can be driven. In this case, a low-resistance conductor layer such as a W layer needs to be formed adjacent to the individual N⁻ layers.

In addition, although the source line SL is negatively biased to withdraw a group of holes from the channel region 7 serving as the floating body FB during the erase operation in the first embodiment, the erase operation may also be performed by negatively biasing the bit line BL instead of the source line SL or by negatively biasing the source line SL and the bit line BL. Alternatively, the erase operation may be performed under other voltage conditions. This also applies to other embodiments according to the present invention.

In addition, in the first embodiment, a fixed voltage of, for example, 2 V may be applied as the voltage V_{ErasePL} of the plate line PL irrespective of the mode of operation. In addition, a voltage of, for example, 0 V may be applied as the voltage V_{ErasePL} of the plate line PL only during erase. In addition, a fixed voltage or a time-varying voltage may be applied as the voltage V_{ErasePL} of the plate line PL as long as the voltage satisfies the conditions where the dynamic flash memory operation can be performed.

In addition, various embodiments and modifications of the present invention can be made without departing from the broad spirit and scope of the present invention. In addition, the foregoing embodiments are intended to illustrate examples of the present invention and not to limit the scope of the present invention. The foregoing embodiments and modifications can be used in any combination thereof. Furthermore, some of the features of the foregoing embodiments may be excluded as needed, and such embodiments are also included within the scope of the technical idea of the present invention.

A memory device including a semiconductor element according to an embodiment of the present invention provides high-density, high-performance dynamic flash memory.

What is claimed is:

1. A memory device including a semiconductor element, comprising:
a first semiconductor base disposed above a substrate, the first semiconductor base standing in a direction perpendicular to the substrate or extending in a direction parallel to the substrate;
a second semiconductor base connected to the first semiconductor base and extending in the same direction as the first semiconductor base;
a first impurity region connected to the first semiconductor base;
a second impurity region connected to the second semiconductor base;
a first gate insulating layer surrounding a portion or an entirety of a side surface of the first semiconductor base;
a second gate insulating layer surrounding a portion or an entirety of a side surface of the second semiconductor base;
a first gate conductor layer covering the first gate insulating layer; and
a second gate conductor layer covering the second gate insulating layer,
wherein, in a sectional view as viewed in an extension direction in which the first semiconductor base and the second semiconductor base are connected together, an outer periphery line of the first semiconductor base at a junction between the first semiconductor base and the second semiconductor base is identical to or located outside an outer periphery line of the second semiconductor base at the junction, and an outer periphery line of the second semiconductor base at a position away from the junction is located inside the outer periphery line of the first semiconductor base, and
voltages applied to the first impurity region, the second impurity region, the first gate conductor layer, and the second gate conductor layer are controlled to perform a data write operation, a data read operation, and a data erase operation.

2. The memory device according to claim 1, wherein a length of the first semiconductor base is longer than or equal to a length of the second semiconductor base in the extension direction in which the first semiconductor base and the second semiconductor base are connected together.

3. The memory device according to claim 1, wherein an area of a surface of the first gate conductor layer is greater than an area of a surface of the second gate conductor layer.

4. The memory device according to claim 1, wherein
the extension direction in which the first semiconductor base and the second semiconductor base are connected together is a direction perpendicular to the substrate, and
is plan view, an outer periphery line of the second semiconductor base at a position adjoining the second impurity region is located inside an outer periphery line of the second semiconductor base at a position adjoining the first semiconductor base.

5. The memory device according to claim 1, wherein
the extension direction in which the first semiconductor base and the second semiconductor base are connected together is a direction perpendicular to the substrate, and
in plan view, an outer periphery line of the first semiconductor base at a position adjoining the first impurity region is located outside an outer periphery line of the first semiconductor base at a position adjoining the second semiconductor base.

6. The memory device according to claim 1, wherein
a wiring line connected to the first impurity region is a source line, a wiring line connected to the second impurity region is a bit line, a wiring line connected to the first gate conductor layer is a first drive control line, and a wiring line connected to the second gate conductor layer is a word line, and
voltages applied to the source line, the bit line, the first drive control line, and the word line are controlled to perform the data erase operation, the data write operation, and the data read operation.

7. The memory device according to claim 1, wherein a first gate capacitance between the first gate conductor layer and the first semiconductor base is greater than a second gate capacitance between the second gate conductor layer and the second semiconductor base.

8. The memory device according to claim 1, comprising:
the first semiconductor base standing perpendicular to the substrate;
the second semiconductor base standing on the first semiconductor base;
the first impurity region on the substrate;
the second impurity region on the second semiconductor base;
the first gate insulating layer surrounding a portion or the entirety of the side surface of the first semiconductor base;
the second gate insulating layer surrounding a portion or the entirety of the side surface of the second semiconductor base;
the first gate conductor layer surrounding the first gate insulating layer;
the second gate conductor layer surrounding the second gate insulating layer; and
a first insulating layer between the first gate conductor layer and the second gate conductor layer.

9. The memory device according to claim 1, wherein a cross-sectional area of the first semiconductor base at a position adjoining the second semiconductor base is smaller than a cross-sectional area of the first semiconductor base at a position adjoining the first impurity region.

10. The memory device according to claim 1, wherein a cross-sectional area of the second semiconductor base at a position adjoining the first semiconductor base is greater than a cross-sectional area of the second semiconductor base at a position adjoining the second impurity region.

11. The memory device according to claim 1, wherein the first impurity region, the second impurity region, the first gate conductor layer, and the second gate conductor layer are configured to perform:
a data write operation of generating a group of electrons and a group of holes by an impact ionization phenomenon with a current flowing between the first impurity region and the second impurity region or by a gate-induced drain leakage current in a first boundary region between the first semiconductor base and the second semiconductor base, in a second boundary region between the first impurity region and the first semiconductor base, or in a third boundary region between the second impurity region and the second semiconductor base, discharging, of the group of generated electrons and the group of generated holes, the group of electrons from the first semiconductor base and the second semiconductor base, and allowing some or all of the group of holes to remain in one or both of the first semiconductor base and the second semiconductor base; and
a data erase operation of discharging, of the group of holes, a group of remaining holes from the first semiconductor base and the second semiconductor base.

12. The memory device according to claim 1, wherein one or both of the first gate conductor layer and the second gate conductor layer are split into two segments in a cross-section in a direction perpendicular to the direction in which the first semiconductor base and the second semiconductor base extend.

13. The memory device according to claim 1, wherein the first gate conductor layer is split into two segments is the direction in which the first semiconductor base and the second semiconductor base extend.

14. The memory device according to claim 13, wherein the two segments of the split first gate conductor layer are driven synchronously or asynchronously.
